(19) United States
(12) Patent Application Publication
(10) Pub. No.: US 2005/0178334 A1
(43) Pub. Date: Aug. 18, 2005

(54) Susceptor Unit and Apparatus in Which the Susceptor Is Installed

(75) Inventors: Kenji Shinma, Itami-shi, Hyogo (JP); Hirohiko Nakata, Itami-shi, Hyogo (JP); Masuhiro Natsuhara, Itami-shi, Hyogo (JP)

Correspondence Address: JUDGE PATENT FIRM;RIVIERE SHUKUGAWA 3RD FL., 3-1 WAKAMATSU-CHO, NISHINOMIYA-SHI, HYOGO, 662-0035, JP

(73) Assignee: SUMITOMO ELECTRIC INDUSTRIES, LTD., Osaka-shi (JP)

(21) Appl. No.: 10/906,325

(22) Filed: Feb. 15, 2005

(30) Foreign Application Priority Data
Feb. 16, 2004 (JP) JP-2004-038318

(51) Int. Cl. C23C 16/00

(52) U.S. Cl. 118/725

(57) ABSTRACT

Affords a susceptor unit in which the temperature uniformity of the susceptor baseplate is enhanced, and devices in which such a susceptor unit is installed. The susceptor unit is made up of a susceptor baseplate for carrying an object to be heated and performing heating operations on the object, and a containment for shielding the susceptor baseplate. In this susceptor unit, the shielding containment shields at least the surface of the susceptor baseplate that forms a lateral side with respect to the baseplate's heated-object-carrying face; and the difference between the maximum and the minimum separations in the encompassing interval between the lateral side of the susceptor baseplate and, facing onto the baseplate lateral side, the inside surface of the shielding containment is not more than 2.2 mm. In implementations including a cooling block, the shielding extends over the lateral side of the cooling block as well.

### BACKGROUND OF THE INVENTION

1. Field of the Invention

The present invention relates to susceptor units employed in heating processes requiring a high level of temperature uniformity, and to apparatuses in which such susceptor units are installed. In particular the invention relates to susceptor units in apparatus associated with semiconductor and flat-panel display fabrication—such as etchers and sputtering systems, plasma CVD, low-pressure CVD, metal CVD, dielectric CVD, low-k CVD and MOCVD devices, degassing and ion implantation devices, and coater/developers—into which an object to be processed is loaded and the object is heated in order to implement predetermined processes on the object; and the invention relates to semiconductor manufacturing/inspection apparatuses, as well as flat-panel display manufacturing/inspection apparatuses, in which such susceptor units are installed.

2. Description of the Background Art

In the process of manufacturing semiconductors or liquid crystals, various processes such as film deposition and etching have traditionally been carried out on the semiconductor substrates (wafers) or liquid-crystal display (LCD) glass that are the processed objects. In the processing equipment in which such operations on semiconductor substrates or LCD glass are carried out, ceramic susceptor baseplates are employed for retaining and for heating the semiconductor substrates or LCD glass.

For example, in the course of photolithography, a resist mask is patterned onto a wafer. In this procedure, after a post-washed wafer is baked dry and cooled, the resist is applied to the wafer frontside, the wafer is loaded onto a ceramic susceptor inside the photolithography tool, and after being dried, the wafer is subjected to exposing, developing, and related processes. In such photolithographic procedures, the temperature when the resist is dried has a large impact on the quality of the coated film, as a consequence of which uniformity in the temperature of the ceramic susceptor baseplate during the process is crucial.

In CVD procedures as another example, a wafer is washed and dried, and then the wafer is loaded onto a ceramic susceptor baseplate inside the CVD reactor, and dielectric films and metallic films are deposited onto the wafer frontside by chemical reactions. Inasmuch as the temperature during the chemical reactions significantly influences the quality of the dielectric and metallic films, here too the uniformity of the ceramic susceptor baseplate temperature is crucial.

Ceramic susceptor baseplates in semiconductor manufacturing systems are installed supported in a support chamber in a system tool, and therein a way of improving the susceptor temperature uniformity by having the ceramic susceptor baseplate and the support chamber be out of contact is disclosed in Japanese Unexamined Pat. App. Pub. No. 2002-252270.

Scaling-up of semiconductor substrates as well as LCD glass has been moving forward in recent years. For example, with the silicon (Si) wafers that are semiconductor substrates, a transition from 8-inch to 12-inch is in progress. Likewise with LCD glass, scaling-up to an extremely large 1500 mm×1800 mm, for example, is underway. Consequent on this enlarging in diametric span of semiconductor substrates as well as LCD glass, that the temperature distribution in the retaining face (heating face) of ceramic susceptor baseplates be within ±1.0% has become a necessity; that it be within ±0.5% has, moreover, come to be the expectation.

Nevertheless, it has been discovered that even with the support chamber and the ceramic susceptor baseplate out of contact, as in Pat. App. Pub. No. 2002-252270, the temperature uniformity of a ceramic susceptor baseplate once having been installed in a tool in, for example, a semiconductor manufacturing system is at times compromised. The present invention was arrived at as the result of various studies into the causes of such deterioration in susceptor-baseplate temperature uniformity.

Specifically, it was discovered that irregularities in the spacing between the ceramic susceptor baseplate and the support chamber produce irregularities in the distribution of temperature in the baseplate, with the susceptor-baseplate temperature distribution at times going beyond ±1.0%.

Meanwhile, reduction in the time it takes to process semiconductor substrates and LCD glass is being pursued, and thus susceptor units with built-in cooling blocks for rapidly cooling the ceramic susceptor baseplate are being developed; but in such implementations as well, there is no change in the demands for thermal uniformity in the temperature distribution.

### SUMMARY OF THE INVENTION

Given the needs in the susceptor art as discussed above, an object of the present invention is to make available a susceptor unit in which the temperature uniformity of the susceptor baseplate is enhanced, and also to provide a device in which such a susceptor unit is installed. A particular object of the invention is, in a susceptor unit having a built-in cooling block, to provide a susceptor unit in which the temperature uniformity in the face of the susceptor baseplate that carries semiconductor substrates or LCD glass is markedly improved (in which the uniformity in temperature across the entire heated-object face is improved). A further object is to make available semiconductor manufacturing/inspection apparatuses, as well as flat-panel display manufacturing/inspection apparatuses, in which such a susceptor unit is installed.

A susceptor unit of the present invention is made up of a susceptor baseplate for carrying an object to be heated and performing heating operations on the object, and a containment for shielding the susceptor baseplate. In this susceptor unit, the shielding containment shields at least the surface of the susceptor baseplate that forms a lateral side with respect to the baseplate's heated-object-carrying face; and the difference between the maximum and the minimum separations in the encompassing interval between the lateral side of the susceptor baseplate and, facing onto the baseplate lateral side, the inside surface of the shielding containment is not more than 2.2 mm.

A susceptor unit in another aspect of the present invention is made up of a susceptor baseplate for carrying an object to be heated and performing heating operations on the object, a cooling block furnished with a means for being brought into abutment against and being parted off of the susceptor baseplate, and a containment for shielding the susceptor baseplate and the cooling block. This susceptor unit is characterized in that the shielding containment shields the surface of the susceptor baseplate that forms a lateral side with respect to the baseplate's heated-object-carrying face, and in that the shielding containment also shields at least the surface of the cooling block that forms a lateral side with respect to the cooling-block surface that comes into abutment with the susceptor baseplate. In this implementation as well, the difference between the maximum and the minimum measurements of the encompassing separation between the lateral side of the susceptor baseplate and the inside surface of the shielding containment is preferably not more than 2.2 mm.

The separation between the shielding containment and either the lateral side of the susceptor baseplate or the lateral side of the cooling block is preferably 0.4 mm or more, but 6.1 mm or less. More preferable still is that the separation be at least 1.6 mm but no more than 3.1 mm.

It is also preferable that the eccentricity (degree of roundness), as well as the planarity, of the mutually opposing surfaces of the susceptor baseplate and shielding containment be no more than 1.1 mm. Another preferable condition in implementing the present invention is that the surface roughness Rₘₐₓ of the mutually opposing surfaces of the susceptor baseplate and the shielding containment be no more than 1.1 mm.

Also preferable is that the difference between the maximum and minimum measurements of the thickness of the shielding containment be no more than 1.1 mm, while deviation in the height of the lateral side of the shielding containment preferably is no more than 1.6 mm. Furthermore, the emissivity of at least part of the shielding containment surface is preferably 0.5 or less, while at least part of the shielding containment surface is preferably nickel-plated.

In semiconductor manufacturing apparatuses as well as semiconductor inspection apparatuses, and flat-panel display manufacturing apparatuses as well as flat-panel display inspection apparatuses, in which a susceptor unit as summarized above is installed, the baseplate/processed-object temperature uniformity is improved, therefore improving the characteristics, the manufacturing yields, and the reliability of the semiconductors and flat-panel displays produced with the apparatuses.

From the following detailed description in conjunction with the accompanying drawings, the foregoing and other objects, features, aspects and advantages of the present invention will become readily apparent to those skilled in the art.

### BRIEF DESCRIPTION OF THE DRAWINGS

FIG. 1 is a schematic sectional view illustrating one example of the present invention;

FIG. 2 is a schematic plan view illustrating the one example of the present invention;

FIG. 3 is a schematic sectional view illustrating another example of the present invention;

FIG. 4 is schematic plan view illustrating a cooling flowpath; and

FIG. 5 is a schematic view representing variations in the height of a shielding containment of the present invention.

### DETAILED DESCRIPTION OF THE INVENTION

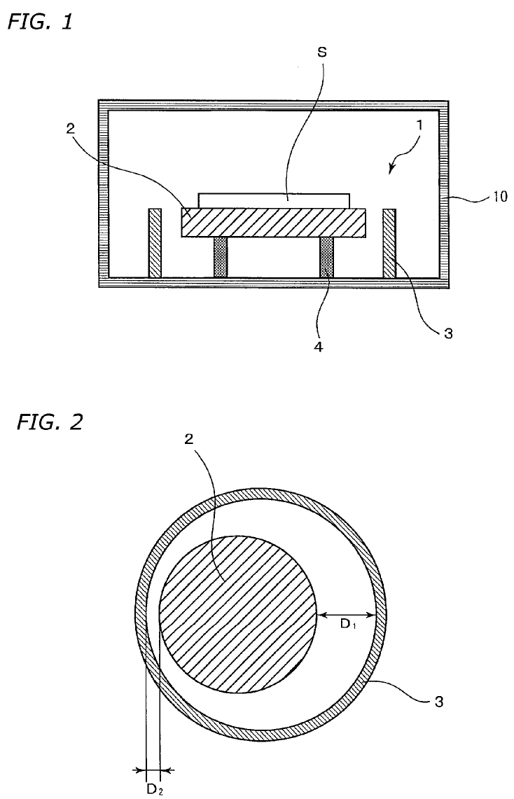

Referring to FIG. 1, an explanation of one embodiment of the present invention will be made. In FIG. 1, in which is one example of embodying the present invention, a susceptor unit 1 is made up of: a susceptor baseplate 2—set up, via support posts 4, within a chamber 10 of, for example, a semiconductor manufacturing apparatus—on which an object s to be heated is carried; and a shielding containment 3 that shields at least the surface of the susceptor baseplate 2 that forms a lateral side (“susceptor baseplate 2 side face” below) with respect to its heated-object-carrying face. One form that the susceptor baseplate may take is discoid, as shown in FIG. 2; and in that implementation the shielding containment preferably is round-cylindrical.

The shielding containment is disposed so as to shield the susceptor baseplate, with the goal of more efficiently heating the object by thermally walling in the heat from the susceptor baseplate so as to keep the heat from being transmitted to other than the heated object, and with the goal of protecting the components and devices other than the heated object from the susceptor-baseplate heat.

The inventors discovered that if the difference between the maximum and the minimum separations in the encompassing interval between the susceptor baseplate 2 side face and, facing onto the side face, the inside surface of the shielding containment is not more than 2.2 mm, then the temperature variation in the face of the heated object swill be within ±1%. For example, in a situation as represented in FIG. 2, |D₁−D₂|≦2.2 mm. More preferably, if |D₁−D₂|≦1.0 mm, then the temperature variation in the face of the heated object scan be within ±0.5%.

The inventors also discovered that with the separation between the susceptor baseplate 2 side face and the shielding containment 3 being from 0.4 mm to 6.1 mm, if the difference between the maximum and the minimum separations in the encompassing interval between the susceptor baseplate 2 side face and, facing onto the side face, the inside surface of the shielding containment 3 is not more than 2.2 mm, then the temperature variation in the face of the heated object swill be within ±0.5%. If the separation is 1.6 mm or more, but 3.1 mm or less, then the temperature variation in the face of the heated object s can be brought to within ±0.2%, which is therefore more preferable still.

Should, however, the separation be than 0.4 mm, then thermal conduction by the gas present between the susceptor baseplate and the shielding containment is no longer negligible, in that the heat in the outer periphery of the susceptor baseplate escapes via the gas toward the shielding containment, thus lowering the temperature along the outer periphery of the susceptor baseplate. By the same token, the susceptor baseplate and the shielding containment being separated by 6.1 mm or more increases thermal diffusion due to convection currents in the gas present between them, likewise lowering the temperature along the outer periphery of the susceptor baseplate.

Furthermore, should the difference between the maximum and the minimum separations in the encompassing interval between the susceptor-baseplate side face and the shielding-containment inside surface exceed 2.2 mm, then the level of thermal conduction and thermal diffusion in the gas in between the susceptor baseplate and the shielding containment would vary between where the minimum separation is and where the maximum separation is, such that non-uniformity in the susceptor baseplate temperature would become serious.

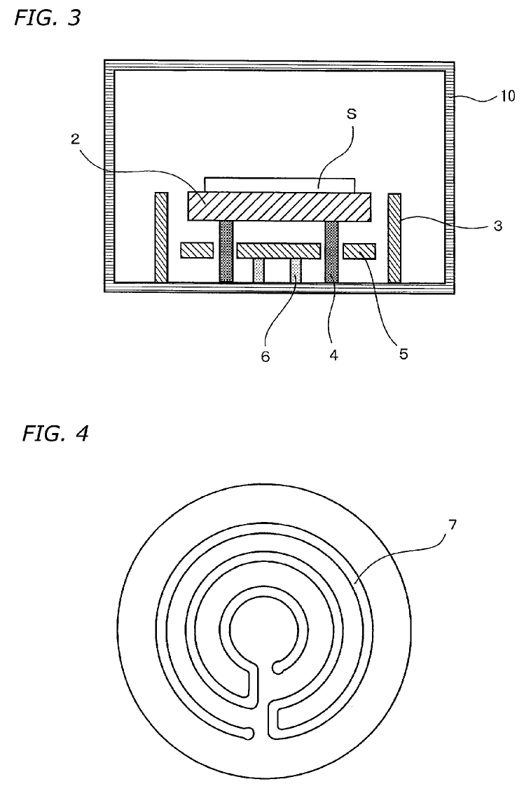

In a susceptor unit in a further aspect of the present invention in which the unit is furnished, as shown in FIG. 3, with a cooling block 5 that, via an elevator means 6 such as an air cylinder, is abuttable on/partable off of the susceptor baseplate 2 so that the susceptor baseplate 2 can be forcibly cooled, the shielding containment 3 shields the susceptor-baseplate side face, and shields at least the surface of the cooling block that forms a lateral side (cooling-block side face) with respect to the cooling-block surface that comes into abutment with the susceptor baseplate. It will be appreciated that in FIG. 3 the cooling block 5 is shown in its parted-off state.

In a case in which the cooling-block side face is not shielded, heat in the outer periphery of the cooling-block having been heated by radiant heat from the susceptor baseplate escapes, on account of which temperature variation is produced in the cooling block. This temperature variation amounts to variation in the quantity of heat that radiates from the cooling block to the susceptor baseplate, and proves to be a factor that produces temperature variation in the susceptor baseplate. Accordingly, it is desirable that the cooling block be shielded as well.

Also in a susceptor unit implementation furnished with a cooling block, it is preferable that the difference between the maximum and the minimum separations in the encompassing interval between the susceptor-baseplate side face and the shielding-containment inside surface be not more than 2.2 mm, wherein it was further discovered that with the separation between the susceptor-baseplate side face and the shielding containment being 0.4 mm or more, but 6.1 mm or less, if the difference between the maximum and the minimum separations in the encompassing interval between the susceptor-baseplate side face and, facing onto the side face, the inside surface of the shielding containment is not more than 2.2 mm, then the temperature variation in the face of the heated object swill be within ±0.5%. If the separation is from 1.6 mm to 3.1 mm, then the temperature variation in the face of the heated object s can be brought to within ±0.2%, which is therefore more preferable still.

Should, however, the separation be than 0.4 mm, then thermal conduction by the gas present between the susceptor baseplate and the shielding containment is no longer negligible, in that the heat in the outer periphery of the susceptor baseplate escapes via the gas toward the shielding containment, thus lowering the temperature along the outer periphery of the susceptor baseplate. By the same token, the susceptor baseplate and the shielding containment being separated by 6.1 mm or more increases thermal diffusion due to convection currents in the gas present between them, likewise lowering the temperature along the outer periphery of the susceptor baseplate.

Furthermore, should the difference between the maximum and the minimum separations in the encompassing interval between the susceptor-baseplate side face and the shielding-containment inside surface exceed 2.2 mm, then the level of thermal conduction and thermal diffusion in the gas in between the susceptor baseplate and the shielding containment would vary between where the minimum separation is and where the maximum separation is, such that non-uniformity in the susceptor baseplate temperature would become serious.

As substances for the shielding containment, metals, such as aluminum, stainless steel, tungsten, molybdenum, copper or chrome, are preferable for their workability, mechanical strength, and resistance to heat. Oxides of these metals or alloys of these metals are also preferable. Particularly preferable are materials that do not generate rust in manufacturing procedures in which micro-operations are implemented, such as in the stages of fabricating semiconductors and liquid-crystal panels. With materials whose thermal conductivity is low being preferable for better insulating, and taking cost and other factors into consideration, stainless steel is, moreover, the most preferable.

As far as the height of the shielding containment is concerned, it is desirable that it not be higher than the heated-object-carrying face of the susceptor baseplate; thus the height preferably is made the same as or somewhat lower than that of the heated-object-carrying face. When semiconductor substrates or LCD glass are as an object to be heated placed into a device in which a susceptor unit is installed and various heating processes are carried out on the object, the general practice is to run a laminar flows of an ambient gas over the object being heated. This is done in order to eliminate gases arising from the heating-processed object by its being heated, as well as to increase the reproducibility and uniformity of the heating operations by creating, with good repeatability, a uniform flow of ambient gasses.

It is unadvisable for the height of the shielding containment to be higher than the heated-object-carrying face of the susceptor baseplate, because then the laminar flow of ambient gas would be disturbed. Another consideration is that to remove the heated object after the heating operations are finished, in general the heated object is lifted up by thrust pins, a conveying fork is inserted in the gap created in between the susceptor baseplate and the heated object, and the heated object is loaded onto the conveying fork and taken out. Thus in that situation, it would disadvantageous for the height of the shielding containment to be higher than the heated-object-carrying face of the susceptor baseplate, in that the extent to which the thrust pins lift would have to be made greater, which would enlarge the size of the device overall.

Another preferable condition for the shielding containment is that deviations in its height be no greater than 1.6 mm, because this decreases variation in the temperature of the object being heated. Bringing deviation in the height of the shielding containment to within 1.6 mm makes it possible to bring temperature variation in the heated object to within ±0.2%. Compared with the portion of the susceptor-baseplate side face that is shielded, in the portion that is not shielded the amount of radiant heat due to emission and convection is greater, which lowers the temperature of the susceptor baseplate. Inasmuch as containment-height deviation greater than 1.6 mm increases the baseplate unshielded portion, temperature variation in the susceptor baseplate becomes significant.

Still another preferable condition for the shielding containment is that among its surfaces, the emissivity of at least the face that opposes the susceptor baseplate and the cooling block be no more than 0.5. The amount of emanated heat from the susceptor baseplate that the shielding containment absorbs, and the amount of heat radiated to the exterior from the shielding containment increase when the emissivity is greater than 0.5, which consequently increases the amount of radiant heat in the vicinity of the susceptor-baseplate outer margin, and enlarges the temperature variation in the susceptor baseplate.

Yet another preferable condition for the shielding containment is that among its surfaces, at least the face that opposes the susceptor baseplate and the cooling block be nickel-plated. The emissivity and the heat-transfer coefficient of the shielding containment vary depending on the condition of the surface. Due to heat from the baseplate during use, oxidation or a similar chemical transformation that alters the condition of the containment surface gradually occurs in the shielding-containment face that opposes the susceptor baseplate, consequently affecting the susceptor-baseplate temperature variation. In this regard, nickel-plating at least the face among the shielding containment surfaces that faces against the susceptor baseplate and the cooling block can control such elapsed-time changes in the shielding-containment surface. It is particularly preferable that the nickel coating be implemented by an electroless plating process (which also goes by the name Kanigen® plating).

Ceramic is the substance of choice for a susceptor baseplate of the present invention. Problems with particles sticking onto process wafers make utilizing metal for the baseplate less desirable. As far as the ceramic itself is concerned, if uniformity in baseplate temperature distribution is stressed, then either aluminum nitride or silicon carbide, both of which are of high thermal conductivity, is preferable. If the emphasis is on reliability, then silicon nitride is preferable for its high degree of strength and its ability to withstand thermal shock. And if cost is the deciding factor, then aluminum nitride is the preferable ceramic.

When the cost/performance balance is taken into consideration, aluminum nitride (AlN) is an ideal choice from among these ceramics. In the following, a method according to the present invention of manufacturing a susceptor baseplate in the case of AlN will be detailed.

AlN raw material powder whose specific surface area is 2.0 to 5.0 m²/g is preferable. The sinterability of the aluminum nitride declines if the specific surface area is less than 2.0 m²/g. Handling proves to be a problem if on the other hand the specific surface area is over 5.0 m²/g, because the powder coherence becomes extremely strong. Furthermore, the quantity of oxygen contained in the raw-material powder is preferably 2 wt. % or less. In sintered form, the thermal conductivity of the material deteriorates if the oxygen quantity is in excess of 2 wt. %. It is also preferable that the amount of metal impurities other than aluminum contained in the raw-material powder be 2000 ppm or less. The thermal conductivity of a sintered compact of the powder deteriorates if the amount of metal impurities exceeds this range. In particular, the content respectively of Group IV elements such as Si, and elements of the iron family, such as Fe, which as metal impurities have a serious worsening effect on the thermal conductivity of a sintered compact, is advisably 500 ppm or less.

Because AlN is not a readily sinterable material, adding a sintering promoter to the AlN raw-material powder is advisable. The sintering promoter added preferably is a rare-earth element compound. Since rare-earth element compounds during sintering react with aluminum oxides or aluminum oxynitrides present on the surface of the particles of the aluminum nitride powder, acting to promote densification of the aluminum nitride and to eliminate oxygen being a causative factor that worsens the thermal conductivity of the sintered aluminum nitride article, they enable the thermal conductivity of the sintered aluminum nitride article to be improved.

Yttrium compounds, whose oxygen-eliminating action is particularly pronounced, are preferable rare-earth element compounds. The amount added is preferably 0.01 to 5 wt. %. If less than 0.01 wt. %, producing ultrafine sintered materials is problematic, along with which the thermal conductivity of the sintered parts deteriorates. Added amounts in excess of 5 wt. % on the other hand lead to sintering promoter being present at the grain boundaries in the sintered aluminum nitride article, and consequently, if the compact is employed under a corrosive atmosphere, the sintering promoter present along the grain boundaries gets etched, becoming a source of loosened grains and particles. More preferably the amount of sintering promoter added is 1 wt. % or less. Being less than 1 wt. %, the sintering promoter will no longer be present even at the grain boundary triple points, which improves the corrosion resistance.

To characterize the rare-earth compounds further: oxides, nitrides, fluorides, and stearic oxide compounds may be employed. Among these, oxides, being inexpensive and readily obtainable, are preferable. By the same token, stearic oxide compounds are especially suitable since they have a high affinity for organic solvents, and if the aluminum nitride raw-material powder, sintering promoter, etc. are to be mixed together in an organic solvent, the fact that the sintering promoter is a stearic oxide compound will heighten the miscibility.

Next, a predetermined volume of solvent, a binder, and further, a dispersing agent or a coalescing agent as needed, are added to the aluminum nitride raw-material powder and powdered sintering promoter, and the mixture is blended together. Possible mixing techniques include ball-mill mixing and mixing by ultrasound. Mixing techniques of this sort allow a raw-material slurry to be produced.

The obtained slurry is molded, and the molded product is sintered to yield a sintered aluminum-nitride part. Co-firing and metallization are two possible methods as a way of doing this.

Metallization will be described first. Granules are prepared from the slurry by spray-drying it, or by means of a similar technique. The granules are inserted into a predetermined mold and subject to press-molding. The pressing pressure therein desirably is 9.8 MPa or more. With pressure less than 9.8 MPa, sufficient strength in the molded part cannot be produced in most cases, making the piece liable to break in handling.

Although the density of the molded part will differ depending on the amount of binder contained and on the amount of sintering promoter added, the density is preferably 1.5 g/cm³ or more. A density of less than 1.5 g/cm³ would mean a relatively large distance between particles in the raw-material powder, which would hinder the progress of the sintering. At the same time, the molded product density preferably is 2.5 g/cm³ or less. Densities of more than 2.5 g/cm³ would rule out sufficiently eliminating the binder from within the molded product in the degreasing process of the ensuing manufacturing procedure. It would consequently prove difficult to produce an ultrafine sintered part as described earlier.

Next, the molded product is heated within a non-oxidizing atmosphere to put it through a degreasing process. Carrying out the degreasing process under an oxidizing atmosphere such as air would degrade the thermal conductivity of the sinter, because the AlN powder would become superficially oxidized. For the non-oxidizing ambient gases, nitrogen and argon are preferable. The heating temperature in the degreasing process is preferably 500° C. or more and 1000° C. or less. With temperatures of less than 500° C., carbon is left remaining in excess within the molded part following the degreasing process because the binder cannot sufficiently be eliminated, which interferes with sintering in the subsequent sintering procedure. On the other hand, at temperatures of more than 1000° C., the amount of carbon left remaining turns out to be too little, such that the ability to eliminate oxygen from the oxidized coating superficially present on the surface of the AlN powder is compromised, degrading the thermal conductivity of the sintered part.

Another condition is that the amount of carbon left remaining within the molded product after the degreasing process is preferably 1.0 wt. % or less. Since carbon remaining in excess of 1.0 wt. % interferes with sintering, an ultrafine sintered part cannot be produced.

Next, sintering is carried out. The sintering is carried out within a non-oxidizing nitrogen, argon, or like atmosphere, at a temperature of 1700 to 2000° C. Therein the moisture contained in the ambient gas, such as nitrogen, that is employed is preferably −30° C. or less given in dew point. If the atmosphere were to contain more moisture than this, the thermal conductivity of the sintered part would likely be compromised, because the AlN would react with the moisture within the ambient gas during sintering and form nitrides. Another preferable condition is that the volume of oxygen within the ambient gas be 0.001 vol. % or less. A larger volume of oxygen would lead to a likelihood of the AlN becoming superficially oxidized, impairing the thermal conductivity of the sintered part.

As another condition during sintering, the jig employed is suitably a boron-nitride (BN) molded article. Inasmuch as the jig as a BN molded article will be sufficiently heat resistant against the sintering temperatures, and superficially will have solid lubricity, friction between the jig and the molded part when the baseplate contracts during sintering will be lessened, which will enable sinter products with little distortion to be produced.

The obtained sintered part is subjected to processing according to requirements. In cases where a conductive paste is to be screen-printed onto the sintered part in the ensuing manufacturing steps, the surface roughness is preferably 5 μm or less in Ra. If over 5 μm, in screen printing to form a circuit on the compact, defects such as blotting or pinholes in the pattern are liable to arise. More suitable is a surface roughness of 1 μm or less in Ra.

In polishing to the abovementioned surface roughness, although cases in which screen printing is done on both sides of the sintered part are a matter of course, even in cases where screen printing is effected on one side only, the polishing process should also be carried out on the surface on the side opposite the screen-printing face. This is because polishing only the screen-printing face would mean that during screen printing, the sintered part would be supported on the unpolished face, and in that situation burrs and debris would be present on the unpolished face, destabilizing the fixedness of the sintered part such that the circuit pattern might not be drawn well by the screen printing.

Furthermore, at this point the thickness uniformity (parallelism) between the processed faces is preferably 0.5 mm or less. Thickness uniformity exceeding 0.5 mm can lead to large fluctuations in the thickness of the conductive paste during screen printing. Particularly suitable is a thickness uniformity of 0.1 mm or less. Another preferable condition is that the planarity of the screen-printing face be 0.5 mm or less. If the planarity exceeds 0.5 mm, in that case too there can be large fluctuations in the thickness of the conductive paste during screen printing. Particularly suitable is a planarity of 0.1 mm or less.

Screen printing is used to spread a conductive paste and form the electrical circuit onto the sintered part having undergone the polishing process. The conductive paste can be obtained by mixing together with a metal powder an oxide powder, a binder, and a solvent according to requirements. The metal powder is preferably tungsten, molybdenum or tantalum, since their thermal expansion coefficients match those of ceramics.

Adding the oxide powder to the conductive paste is also to enhance the strength with which it bonds to AlN. The oxide powder preferably is an oxide of Group IIa or Group IIIa elements, or is Al₂O₃, SiO₂, or a like oxide. Yttrium oxide is especially preferable because it has very good wettability with AlN. The amount of such oxides added is preferably 0.1 to 30 wt. %. If the amount is less than 0.1 wt. %, the bonding strength between AlN and the metal layer being the circuit that has been formed is compromised. On the other hand, amounts in excess of 30 wt. % elevate the electrical resistance of the metal layer that is the electrical circuit.

The thickness of the conductive paste is preferably 5 μm or more and 100 μm or less in terms of its post-drying thickness. If the thickness is less than 5 μm the electrical resistance would be too high and the bonding strength would decline. Likewise, if in excess of 100 μm the bonding strength would be compromised in that case as well.

Also preferable is that in the patterns for the circuits that are formed, in the case of the heater circuit (resistive heating element circuit), the pattern spacing be 0.1 mm or more. With a spacing of less than 0.1 mm, shorting will occur when current flows in the resistive heating element and, depending on the applied voltage and the temperature, leakage current is generated. Particularly in cases where the circuit is employed at temperatures of 500° C. or more, the pattern spacing preferably should be 1 mm or more; more preferable still is that it be 3 mm or more.

Then, after the conductive paste is degreased, baking follows. Degreasing is carried out within a non-oxidizing nitrogen, argon, or like atmosphere. The degreasing temperature is preferably 500° C. or more. At less than 500° C., elimination of the binder from the conductive paste is inadequate, leaving behind in the circuit metal layer carbon that when the circuit is baked on will form metal carbides and consequently raise the electrical resistance of the metal layer.

The baking is suitably done within a non-oxidizing nitrogen, argon, or like atmosphere at a temperature of 1500° C. or more. At temperatures of less than 1500° C., the post-baking electrical resistance of the metal layer turns out too high because the baking of the metal powder within the paste does not proceed to the grain growth stage. A further baking parameter is that the baking temperature should not surpass the sintering temperature of the ceramic produced. If the conductive paste is baked at a temperature beyond the sintering temperature of the ceramic, dispersive volatilization of the sintering promoter incorporated within the ceramic sets in, and moreover, grain growth in the metal powder within the conductive paste is accelerated, impairing the bonding strength between the ceramic and the metal layer.

Next, in order to ensure that the formed metal layer is electrically isolated, an insulative coating can be formed on the metal layer. The insulative coating substance is not particularly limited as long as its reactivity with the electrical circuit is low, and its difference with AlN in thermal expansion coefficient is 5.0×10⁻⁶/K or less. Substances such as glass ceramic or AlN, for example, can be employed. A coating can be formed, for example, by putting these substances into paste form, screen-printing the paste on at a predetermined thickness, degreasing the coating as needed, and then baking it at a predetermined temperature. The ceramic baseplate in this state may also be made into a ceramic susceptor by attaching to electrodes to it for supplying power to the metal layer.

Next, in the present method, the ceramic as substrates furthermore can be laminated according to requirements. Lamination may be done via an adhesive. The adhesive—being a compound of Group IIa or Group IIIa elements, and a binder and solvent, added to an aluminum oxide powder or aluminum nitride powder and made into a paste—is spread onto the joining surface by a technique such as screen printing. The thickness of the applied adhesive is not particularly restricted, but preferably is 5 μm or more. Joining defects such as pinholes and adhesive irregularities are liable to arise in the adhesive layer at thicknesses of less than 5 μm.

The ceramic substrates onto which the adhesive has been spread are degreased within a non-oxidizing atmosphere at a temperature of 500° C. or more. The ceramic substrates are thereafter joined to one another by stacking together ceramic substrates to be laminated, applying a predetermined load to the stack, and heating it within a non-oxidizing atmosphere. The load preferably is 5 kPa or more. With loads of less than 5 kPa sufficient joining strength will not be obtained, and otherwise the joining defects just noted will be prone to occur.

Although the heating temperature for joining is not particularly restricted as long as it is a temperature at which the ceramic substrates adequately bond to one another via the joining layers, preferably it is 1500° C. or more. With adequate joining strength proving difficult to gain at less than 1500° C., defects in joining are liable to arise. Nitrogen or argon is preferably employed for the non-oxidizing atmosphere during the degreasing and joining just discussed.

A ceramic sinter laminate that serves as a susceptor baseplate can be produced as in the foregoing. As far as the electrical circuit is concerned, it should be understood that if it is a heater circuit for example, then a molybdenum coil can be utilized, and in cases such as with electrostatic-chuck electrodes or RF electrodes, molybdenum or tungsten mesh can be, without employing conductive paste.

In such cases, the molybdenum coil or the mesh can be built into the AlN raw-material powder, and the ceramic susceptor baseplate can be fabricated by hot pressing. While the temperature and atmosphere in the hot press may be on par with the AlN sintering temperature and atmosphere, the hot press desirably applies a pressure of 0.98 MPa or more. With pressure of less than 0.98 MPa, the ceramic susceptor baseplate might not demonstrate its performance capabilities, because interstices arise between the AlN and the molybdenum coil or the mesh.

It should be noted that in implementations in which the sintered aluminum-nitride part is produced by metallization, silver (Ag), palladium (Pd) or platinum (Pt), as well as alloys of these metals may be utilized for the metal powder used in the conductive paste. Although the thermal expansion coefficient of these metals is larger than that of AlN, their sintering temperature is low compared with that of W or Mo, which allows the influence of their difference in thermal expansion coefficient as against that of AlN to be diminished.

It will be appreciated that the electrical resistance can be adjusted by the relative proportions of these metals. Making the ratio of Ag greater enables the sheet resistance to be lowered, while making the ratio of Pd or Pt greater enables the sheet resistance to be raised.

Furthermore, oxides of Group IIIa elements, or SiO₂, Al₂O₃, B₂O₃, copper oxide, or zinc oxide, can be added to heighten the bonding strength between AlN and Ag, Pd, Pt, or their alloys. Adding a binder and an organic solvent renders a conductive paste. The electrical circuit is formed by screen-printing, likewise as noted earlier, this conductor paste to spread it on. The circuit is baked in a 600 to 1000° C. temperature range in air or within an inert-gas ambient.

In order to secure the insulative properties of the formed metal layer, the metal layer can be given an insulative coating. In that case, mixtures of ZnO, SiO₂, Al₂O₃, PbO, etc., and glass ceramics, glass glaze, or heat-resistant synthetic polymers can be used for the insulative-coating substance. These substances may be chosen according to application, use temperature, etc.

To these substances a binder and organic solvent can be added according to need, the mixture can be coated on by screen-printing and, apart from the heat-resistant synthetic polymer, by heat-processing in a 500 to 900° C. temperature range—and in the case of the heat-resistant synthetic polymer, in a 150 to 250° C. temperature range—in air or within an inert-gas ambient the glass, etc. hardens to form an insulative coating.

Co-firing will now be explained. The earlier-described raw-material slurry is molded into sheets by doctor blading. The sheet-molding parameters are not particularly limited, but the post-drying thickness of the sheets advisably is 3 mm or less. The sheet thickness surpassing 3 mm leads to large shrinkage in the drying slurry, raising the probability that fissures will be generated in the sheet.

A metal layer of predetermined form that serves as an electrical circuit is formed onto an abovementioned sheet using a technique such as screen printing to spread onto it a conductive paste. The conductive paste utilized can be the same as that which was descried under the metallization method. Nevertheless, not adding an oxide powder to the conductive paste does not hinder the co-firing method.

Subsequently, the sheet that has undergone circuit formation is laminated with sheets that have not. Lamination is by setting the sheets each into predetermined position to stack them together. Therein, according to requirements, a solvent is spread on between sheets. In the stacked state, the sheets are heated as may be necessary. In cases where the stack is heated, the heating temperature is preferably 150° C. or less. Heating to temperatures in excess of this greatly deforms the laminated sheets. Pressure is then applied to the stacked-together sheets to unitize them. The applied pressure is preferably within a range of from 1 to 100 MPa. At pressures less than 1 MPa, the sheets are not adequately unitized and can peel apart during subsequent manufacturing steps. Likewise, if pressure in excess of 100 MPa is applied, the extent to which the sheets deform becomes too great.

This laminate undergoes a degreasing process as well as sintering, in the same way as with the metallization method described earlier. Parameters such as the temperature in degreasing and sintering, and the amount of carbon are the same as with metallization. A susceptor baseplate having plural electrical circuits can be readily fabricated by printing, in the previously described screen printing of a conductive paste onto sheets, heater circuits, electrostatic-chuck electrodes, etc. respectively onto a plurality of sheets and laminating them. In this way a ceramic sinter laminate that serves as a susceptor baseplate can be produced.

It should be understood that in implementations in which an electrical circuit(s) such as the resistive heating element circuit is formed on the outermost layer of the ceramic laminate, to protect the electric circuit and ensure that it is electrically insulated, an insulative coating can be formed onto the circuit in the same way as described earlier for the metallization method.

The obtained ceramic sinter laminate is subject to processing according to requirements. As a rule, in the sintered state the ceramic sinter laminate usually is not within the precision demanded in semiconductor manufacturing equipment. The planarity of the processed (heated)-object-carrying face as an example of processing precision is preferably 0.5 mm or less; moreover 0.1 mm or less is particularly preferable. The planarity surpassing 0.5 mm is apt to give rise to interstices between the processed object and the susceptor baseplate, keeping the heat of the susceptor baseplate from being uniformly transmitted to the processed object and making the generation of temperature irregularities in the processed object likely.

A further preferable condition is that the surface roughness of the processed-object-carrying face be 5 μm in Ra. If the roughness is over 5 μm in Ra, grains loosened from the AlN due to friction between the susceptor baseplate and the processed object can grow numerous. Grain-loosened particles in that case become contaminants that have a negative effect on processes, such as film deposition and etching, on the processed object. Furthermore, then, a surface roughness of 1 μm or less in Ra is ideal.

### Embodiment 1

100 parts by weight aluminum nitride powder and 0.6 parts by weight yttrium stearate powder were mixed and blended with 10 parts by weight polyvinyl butyral as a binder and 5 parts by weight dibutyl phthalate as a solvent. The mixture was spray dried to prepare granules, which were thereafter pressure-molded, degreased within a nitrogen atmosphere at 700° C., and sintered at 1850° C. to yield an sintered aluminum nitride article. Here, an aluminum nitride powder of 0.6 μm mean particle diameter and 3.4 m²/g specific surface area was utilized. The sintered aluminum nitride article was machined to have a diameter of 330 mm and a thickness of 12 mm.

Furthermore, a tungsten paste was prepared with a tungsten powder of 2.0 μm mean particle diameter being 100 parts by weight, by mixing it with Y₂O₃ at 1 part by weight, 5 parts by weight ethyl cellulose, being a binder, and as a solvent, butyl Carbitol™. A pot mill and a triple-roller mill were used for mixing. This tungsten paste was formed into a heating-element circuit pattern on the machined aluminum nitride disk by screen-printing. This was degreased within a 900° C. nitrogen atmosphere and subsequently baked 6 hours in a nitrogen atmosphere at 1800° C.

A paste of ZnO—B₂O₃—Al₂O₃ glass was spread at a thickness of 100 μm over the surface on which the heating-element circuit pattern was formed, except for a power-supply portion, and baked within a 700° C. nitrogen atmosphere. A tungsten terminal was screw-fastened to the power-supply portion, and further a nickel electrode was screwed to the tungsten terminal to complete a susceptor baseplate.

As a shielding containment, a tubular article made of stainless steel (emissivity: 0.18) was prepared. The susceptor baseplate and the shielding containment were installed as illustrated in FIG. 1 into the chamber 10 of a semiconductor manufacturing device, with the susceptor baseplate 2 being set up on support posts 4, and the shielding containment 3 being installed so as to be the same height as that of the heated-object carrying face of the susceptor baseplate 2. The stainless-steel shielding containment 3 was arranged so that the minimum separation D₂, as illustrated in FIG. 2, from the susceptor baseplate 2, and the difference (D₁−D₂) between the maximum and the minimum separations from the susceptor baseplate 2 would be the measurements set forth in Table I.

Current was passed through the susceptor baseplate to heat it to 220° C., and after the temperature stabilized, the differences between the maximum and minimum temperature readings on a wafer temperature gauge incorporated into the susceptor baseplate were evaluated as the temperature variations. The results are tabulated in Table I.

TABLE I

| | |
|---|---|
| Min. dist. | Max. dist. − min. dist. (mm) |

| (mm) | 0 | 0.5 | 1.0 | 1.5 | 2.0 | 2.2 | 2.4 | |
|---|---|---|---|---|---|---|---|---|
| 0.1 | 3.0 | 3.1 | 3.5 | 3.9 | 4.3 | 4.4 | 5.4 | Temperature |
| 0.3 | 1.3 | 1.6 | 2.0 | 2.5 | 3.0 | 3.3 | 3.8 | variation(° C.) |
| 0.4 | 0.8 | 0.9 | 1.1 | 1.5 | 2.0 | 2.2 | 3.2 | |
| 0.6 | 0.5 | 0.7 | 1.0 | 1.2 | 1.5 | 1.9 | 2.2 | |
| 1.1 | 0.4 | 0.5 | 0.8 | 1.0 | 1.3 | 1.5 | 2.0 | |
| 1.6 | 0.3 | 0.4 | 0.4 | 0.5 | 0.5 | 0.6 | 1.2 | |
| 2.1 | 0.3 | 0.4 | 0.5 | 0.6 | 0.6 | 0.7 | 1.3 | |
| 3.1 | 0.4 | 0.5 | 0.6 | 0.7 | 0.8 | 0.8 | 1.5 | |
| 4.1 | 0.5 | 0.6 | 0.7 | 0.8 | 0.9 | 1.6 | 2.5 | |
| 5.1 | 0.7 | 0.8 | 0.9 | 1.3 | 1.7 | 2.0 | 3.1 | |
| 6.1 | 0.8 | 0.9 | 1.1 | 1.6 | 2.1 | 2.2 | 3.5 | |
| 7.1 | 1.4 | 1.9 | 2.2 | 2.6 | 2.7 | 3.2 | 4.4 | |
| 8.1 | 2.3 | 2.8 | 3.3 | 3.8 | 4.0 | 4.2 | 5.3 | |

In Table I, the numerical value 3.0 in the cell, for example, belonging to the 0.1 mm minimum separation row, and the 0 mm maximum minus minimum separation column, indicates that the temperature variation in the susceptor baseplate was 3.0° C. when the susceptor baseplate and the shielding containment were installed so that the minimum separation D₂ was 0.1 mm and the difference between the maximum and the minimum separationss (D₁−D₂) was 0 mm over the entire circumference.

As is evident from Table I, with the difference between the maximum and the minimum separations between the susceptor baseplate and the shielding containment being 2.2 mm or less, temperature variation in the susceptor baseplate was, quite satisfactorily, within ±1.0%. The instances in which the minimum separation was 0.4 mm to 6.1 mm were favorable, and were particularly good in that range if the separation was not less than 1.6 mm.

### Embodiment 2

An AlN susceptor baseplate was prepared in the same manner as in Embodiment 1. Furthermore, pure aluminum plates 330 mm in diameter, with thicknesses of 12 mm and 7 mm were prepared for a cooling block. The thermal conductivity of the pure aluminum plates was 200 W/mK. Of these, the 12-mm thick aluminum plate was machined to have a 5 mm-wide and 5-mm deep flow path 7, as illustrated in FIG. 4, for passing a coolant. A 2-mm wide and 1-mm deep groove (not shown) for holding an inserted O-ring was formed along the outer circuit of the flow path. Furthermore, through-holes were formed as the inlet and outlet for the coolant. The two aluminum plates were screw-fastened to fix them together with the O-ring inserted in between.

As a shielding containment, a tubular article made of stainless steel (emissivity: 0.18) was prepared. The susceptor baseplate, the cooling block, and the shielding containment were installed as illustrated in FIG. 3 into a chamber 10 of a semiconductor manufacturing device, with the susceptor baseplate 2 being set up on support posts 4, the cooling block 5 being set up on air cylinders 6, and the shielding containment 3 being installed so as to be the same height as that of the heated-object carrying face of the susceptor baseplate 2. The stainless-steel shielding containment 3 was arranged so that the minimum separation D₂, as illustrated in FIG. 2, from the susceptor baseplate 2, and the difference (D₁−D₂) between the maximum and the minimum separations from the susceptor baseplate 2 would be the measurements set forth in Table II.

Current was passed through the susceptor baseplate to heat it to 220° C. in the same manner as in Embodiment 1, and after the temperature stabilized, the differences between the maximum and minimum temperature readings on a wafer temperature gauge incorporated into the susceptor baseplate were evaluated as the temperature variations. The results are tabulated in Table II.

TABLE II

| | |
|---|---|
| Min. dist. | Max. dist. − min. dist. (mm) |

| (mm) | 0 | 0.5 | 1.0 | 1.5 | 2.0 | 2.2 | 2.4 | |
|---|---|---|---|---|---|---|---|---|
| 0.1 | 2.3 | 2.3 | 2.6 | 2.9 | 3.2 | 3.8 | 4.1 | Temperature |
| 0.4 | 0.8 | 0.9 | 1.1 | 1.3 | 1.5 | 1.9 | 2.7 | variation(° C.) |
| 1.1 | 0.5 | 0.6 | 0.8 | 0.8 | 0.9 | 1.0 | 1.4 | |
| 1.6 | 0.3 | 0.4 | 0.4 | 0.4 | 0.4 | 0.5 | 0.9 | |
| 2.1 | 0.3 | 0.3 | 0.4 | 0.5 | 0.5 | 0.5 | 1.0 | |
| 3.1 | 0.3 | 0.4 | 0.5 | 0.5 | 0.6 | 0.6 | 1.1 | |
| 4.1 | 0.4 | 0.5 | 0.5 | 0.6 | 0.7 | 1.3 | 2.1 | |
| 5.1 | 0.5 | 0.6 | 0.7 | 1.3 | 1.5 | 1.7 | 2.4 | |
| 6.1 | 0.6 | 1.2 | 1.4 | 1.5 | 1.8 | 2.2 | 3.1 | |
| 7.1 | 1.1 | 1.5 | 1.7 | 1.9 | 2.2 | 2.6 | 3.6 | |
| 8.1 | 2.1 | 2.2 | 2.5 | 3.0 | 3.2 | 3.3 | 4.3 | |

The form of representation of Table II is the same as that of Table I. As will be understood from Table II, also in susceptor-unit implementations furnished with a cooling block, susceptor baseplate temperature variation could readily be brought to within a quite satisfactory ±0.5% when the difference between the maximum and the minimum separations between the susceptor baseplate and the shielding containment was 2.2 mm or less. The instances in which the minimum separation was 0.4 mm to 6.1 mm were favorable, and were particularly good in that range if the separation was not less than 1.6 mm.

### Embodiment 3

An AlN susceptor baseplate identical to that in Embodiment 1, and a 334-mm diameter stainless-steel shielding containment were installed, in a like manner as in Embodiment 1, into the chamber of a semiconductor manufacturing device. The minimum separation between the susceptor baseplate and the shielding containment was 1.9 mm, and the difference between the maximum and the minimum separations was 0.2 mm.

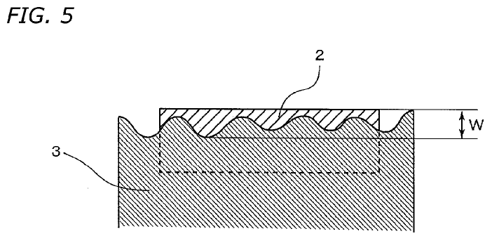

Deviation W, as illustrated in FIG. 5, in the height of the shielding containment was rendered to be the values set forth in Table III. In each case the shielding containment was set so that its highest position(s) was on par with the height of the heated-object carrying face of the susceptor baseplate. The temperature variation at 220° C. was measured in the same manner as in Embodiment 1. The results are tabulated in Table III.

TABLE III

| Shielding-containment height | Temperature variation |
|---|---|
| deviation W (mm) | (° C.) |
| 0.0 | 0.3 |
| 0.5 | 0.4 |
| 1.0 | 0.4 |
| 1.5 | 0.6 |
| 1.6 | 0.8 |
| 1.7 | 1.4 |
| 2.0 | 1.6 |

As will be understood from Table III, when the shielding-containment height deviation was 1.6 mm or less, the temperature uniformity of the susceptor baseplate was, quite favorably, within ±0.2%. When the shielding-containment height deviation exceeded 1.6 mm, the temperature uniformity in the susceptor baseplate was poor. This is presumably because compared with the portion of the susceptor-baseplate lateral face that is shielded, the portion that is not shielded gives off a greater amount of heat through radiation and convection, thus deviation in the height of the containment in excess of 1.6 mm increases the unshielded portion of the susceptor baseplate, resulting in larger baseplate temperature variation.

Meanwhile, even when the shielding containment was set so that the position(s) of lowest deviation in its height was on par with the heated-object carrying face of the susceptor baseplate—that is, when a portion of the shielding containment was higher than the heated-object carrying face of the susceptor baseplate—the temperature variation in the susceptor baseplate was controlled to be within ±0.2% as long as the shielding containment height deviation was 1.6 mm or less.

### Embodiment 4

An AlN susceptor baseplate identical to that in Embodiment 2, a 334-mm diameter stainless-steel shielding containment, and a cooling block made of pure aluminum were installed, in a like manner as in Embodiment 2, into the chamber of a semiconductor manufacturing device. The minimum separation between the susceptor baseplate and the shielding containment was 1.9 mm, and the difference between the maximum and the minimum separations was 0.2 mm.

By forced oxidization of the inside surface of the stainless-steel shielding containment (of the face opposing the susceptor baseplate), without altering its thermal conductivity or specific heat, instances in which the thermal emissivity was varied as set forth in Table IV were prepared. Temperature variation at 220° C. was measured in the same manner as in Embodiment 2. The results are tabulated in Table IV.

TABLE IV

| | Temperature variation |
|---|---|
| Shielding containment emissivity | (° C.) |
| 0.18 | 0.4 |
| 0.5 | 0.7 |
| 0.87 | 2.3 |

As will be understood from Table IV, when the emissivity was 0.5 the temperature variation increased somewhat by comparison to that when the emissivity was 0.18, but the difference was not that significant. However, in the instance in which the emissivity 0.87, the temperature variation proved to be very significant. This is presumably because with greater emissivity of the shielding-containment inside surface, the amount of heat in the shielding containment that was radiant from/absorbed through the susceptor baseplate, and the amount of heat dissipated to the exterior from the shielding containment increased synergistically, increasing the amount of heat that dissipates from the outer margin of the susceptor baseplate and lowering the temperature along the susceptor-baseplate outer margin, which enlarged the temperature variation in the susceptor baseplate.

### Embodiment 5

An AlN susceptor baseplate identical to that in Embodiment 2, a 334 mm-diameter stainless-steel shielding containment, and a cooling block made of pure aluminum were installed, in a like manner as in Embodiment 2, into the chamber of a semiconductor manufacturing device. The minimum separation between the susceptor baseplate and the shielding containment was 1.9 mm, and the difference between the maximum and the minimum separations was 0.2 mm. Here, a stainless-steel shielding containment the surface of which had been subjected to a nickel-plating process was also prepared.

The temperature of the susceptor baseplate was elevated to 360° C. and held at 360° C. for 30 minutes. Subsequently, its temperature variation was measured with a wafer temperature gauge in the same manner as in Embodiment 1. Thereafter, the susceptor baseplate was cooled to 70° C. and again heated to 360° C. This cycle was repeated 1000 times, and the temperature variation at cycle 1000 was also measured. The results are tabulated in Table V.

TABLE V

Temperature variation
(° C.)

| Shielding containment | At 1 cycle | At 1000 cycles |
|---|---|---|
| Unprocessed | 0.4 | 1.7 |
| Nickel-plated | 0.4 | 0.5 |

As will be understood from Table V, in the instance in which the shielding-containment surface had not undergone a nickel-plating process, at 1000 repetitions the temperature variation in the susceptor baseplate became poor, whereas in the instance in which the nickel-plating process had been implemented, the temperature variation in the susceptor baseplate had hardly changed even 1000 repetitions.

On observing the inside surface of the shielding containment after 1000 repetitions, the shielding containment that had undergone a nickel-plating process had retained its metallic luster, while the unprocessed shielding containment had discolored from brown to pale black. This discoloration presumably was the stainless steel having thermally oxidized in part. The discoloration appeared in a mottled pattern, and the emissivity of the discolored areas varied from 0.4 to 0.7. This irregularity in emissivity is believed to have manifested as the temperature variation in the susceptor baseplate.

### Embodiment 6

Susceptor baseplates as illustrated in FIG. 1, having heating element circuits, were fabricated in the same manner as in Embodiment 1. Three baseplate substances were chosen: aluminum oxide, silicon carbide, and silicon nitride.

With the addition of the aluminum-nitride susceptor baseplate used in Embodiment 1, four different susceptor baseplates were heated to raise the temperature from 70° C. to 360° C. at a rate of 20° C. per minute, and were kept at 360° C. for 10 minutes, then their temperature distribution was measured with a wafer temperature gauge. Thereafter, a cycle in which the temperature was lowered to 70° C. at a rate of 20° C. per minute, elevated from 70° C. to 360° C. at a rate of 20° C. per minute, kept at 360° C. for 10 minutes, and lowered from 360° C. to 70° C. at a rate of 20° C. per minute was repeated 1000 times to find the number of times until the susceptor baseplates became damaged. The results are tabulated in Table VI.

TABLE VI

| | Temperature | |
|---|---|---|
| | variation | Count at susceptor |
| Material | (° C.) | breakage |
| Aluminum nitride | 0.4 | No breakage |
| Aluminum oxide | 1.3 | 798 |
| Silicon carbide | 1.1 | No breakage |

As will be understood from Table VI, aluminum nitride and silicon carbide were superior in terms of temperature uniformity. It will also be understood that the reliability of the susceptor baseplates made of the substances other than aluminum oxide was high, in that they did break down in the cycling test. Moreover, it will be appreciated that aluminum nitride proved superior in terms of both temperature uniformity and reliability.

### Embodiment 7

The aluminum nitride susceptor baseplate, stainless-steel shielding containment, and pure aluminum cooling-block used in Embodiment 2 were installed in a resist heat-processing apparatus, with which a photolithography process was performed. The minimum separation between the susceptor baseplate and the shielding containment was 0.9 mm, and the difference between the maximum and the minimum separations was 2.2 mm. The resist used was an ultra-high resolution resist for a 248-nm wavelength KrF excimer laser stepper, and underwent a 90-second pre-bake at 130° C. and a 90-second exposure bake at 130° C., wherein the 3σvariation in 130-nm node linewidth was measured.

The result was a linewidth variation of 8 nm. In contrast, linewidth variation was measured in the same manner with the minimum separation between the susceptor baseplate and the shielding containment being 0.8 mm, and the difference between the maximum and the minimum separations being 2.4 mm, wherein the linewidth was 12 nm. Thus, in accordance with the present invention, inasmuch as the susceptor-baseplate temperature distribution proved to be considerably more uniform than conventional, it was evident that linewidth variation could be sharply reduced.

The fact that linewidth variation could be sharply reduced brings to bear on, for example, transistor semiconductor devices, which are composed of elements that include electrode metal lines, insulating films, and impurity diffusion layers. These elements are extremely minute, measuring from sub-microns down to, in recent years, around 100 nm, and therefore demand great dimensional accuracy.

These elements are formed by going through a variety of manufacturing stages accompanied by heating, such as ultra-thin-film chemical vapor deposition, etching, and photolithography procedures. During these procedures, variation in the heating temperature in the surface of the semiconductor substrates that are the processed objects will produce inconsistencies in the dimensions of the semiconductor device elements. If heating-temperature variation is slight and thus the temperature is uniform, the elements will have less variation in dimensions and thus the device characteristics, manufacturing yields, and reliability will improve.

What is more, because improved dimensional accuracy in the device elements enables designing at even finer resolution, enhanced levels of integration are made possible. In other words, the characteristics of the semiconductor device can be improved. With flat-panel displays also, reduced heating-temperature variation during device fabrication likewise enables improvement in manufacturing yields, makes it possible to uniformize the pixel characteristics over the entire panel, and enables such improving of characteristics as upgrading to high-definition images by microminiaturizing the pixels.

Semiconductor manufacturing apparatuses as well as semiconductor inspection apparatuses, flat-panel display manufacturing apparatuses as well as flat-panel display inspection apparatuses, and photoresist heat-processing apparatuses, in which a susceptor unit according to the present invention is installed, make it possible to improve the characteristics, the manufacturing yields, and the reliability of the semiconductors and flat-panel displays produced.

In accordance with the present invention, the temperature distribution in the heating surface of a susceptor baseplate is improved over what has been conventional. Installing susceptor units having a susceptor baseplate of this sort into all manner of semiconductor manufacturing apparatuses and inspection apparatuses, and into flat-panel display manufacturing apparatuses as well as flat-panel display inspection apparatuses—such as etchers and sputtering systems, plasma CVD, low-pressure CVD, metal CVD, dielectric CVD, low-k CVD and MOCVD devices, degassing and ion implantation devices, and coater/developers—improves the baseplate/processed-object temperature uniformity, therefore improving the characteristics, the manufacturing yields, and the reliability of the semiconductors and flat-panel displays produced.

Only selected embodiments have been chosen to illustrate the present invention. To those skilled in the art, however, it will be apparent from the foregoing disclosure that various changes and modifications can be made herein without departing from the scope of the invention as defined in the appended claims. Furthermore, the foregoing description of the embodiments according to the present invention is provided for illustration only, and not for limiting the invention as defined by the appended claims and their equivalents.

1. A susceptor unit comprising:
a susceptor baseplate for carrying an object to be heated and performing heating operations on the object, said susceptor baseplate therein having a heated-object-carrying face and a surface that forms a lateral side with respect to the heated-object-carrying face; and
a containment for shielding at least the lateral side of said susceptor baseplate, said shielding containment having an inside surface facing onto the baseplate lateral side at an encompassing interval in which the difference between the maximum and the minimum separations between said containment and said baseplate is not more than 2.2 mm.

2. A susceptor unit comprising:
a susceptor baseplate for carrying an object to be heated and performing heating operations on the object, said susceptor baseplate therein having a heated-object-carrying face and a surface that forms a lateral side with respect to the heated-object-carrying face;
a cooling block furnished with a means for a surface of said cooling block to be brought into abutment against and to be parted off of said susceptor baseplate, said cooling block therein having a surface that forms a lateral side with respect to the cooling-block surface that comes into abutment with said susceptor baseplate; and
a containment for shielding the lateral side of said susceptor baseplate, and for shielding at least the lateral side of said cooling block.

3. A susceptor unit as set forth in claim 2, wherein the difference between the maximum and minimum values of an encompassing separation between the lateral side of said susceptor baseplate and an inside surface of said shielding containment is not more than 2.2 mm.

4. A susceptor unit as set forth in claim 1, wherein deviation in the lateral-side height of said shielding containment is no more than 1.6 mm.

5. A susceptor unit as set forth in claim 2, wherein deviation in the lateral-side height of said shielding containment is no more than 1.6 mm.

6. A susceptor unit as set forth in claim 1, wherein the emissivity of at least part of the surface of said shielding containment is 0.5 or less.

7. A susceptor unit as set forth in claim 2, wherein the emissivity of at least part of the surface of said shielding containment is 0.5 or less.

8. A susceptor unit as set forth in claim 1, wherein at least part of the surface of said shielding containment is nickel-plated.

9. A susceptor unit as set forth in claim 2, wherein at least part of the surface of said shielding containment is nickel-plated.

10. A susceptor unit as set forth in claim 1, wherein the chief component of said susceptor baseplate is one selected from aluminum nitride, silicon carbide, silicon nitride, and aluminum oxide.

11. A susceptor unit as set forth in claim 2, wherein the chief component of said susceptor baseplate is one selected from aluminum nitride, silicon carbide, silicon nitride, and aluminum oxide.

12. A susceptor unit as set forth in claim 1, wherein the chief component of said susceptor baseplate is aluminum nitride.

13. A susceptor unit as set forth in claim 2, wherein the chief component of said susceptor baseplate is aluminum nitride.

14. A semiconductor manufacturing apparatus in which a susceptor unit as set forth in claim 1 is installed.

15. A semiconductor manufacturing apparatus in which a susceptor unit as set forth in claim 2 is installed.

16. A semiconductor inspection apparatus in which a susceptor unit as set forth in claim 1 is installed.

17. A semiconductor inspection apparatus in which a susceptor unit as set forth in claim 2 is installed.

18. A flat-panel display manufacturing apparatus in which a susceptor unit as set forth in claim 1 is installed.

19. A flat-panel display manufacturing apparatus in which a susceptor unit as set forth in claim 2 is installed.

20. A flat-panel display inspection apparatus in which a susceptor unit as set forth in claim 1 is installed.

21. A flat-panel display inspection apparatus in which a susceptor unit as set forth in claim 2 is installed.
